(19) United States
(12) Patent Application Publication
(10) Pub. No.: US 2010/0038584 A1
(43) Pub. Date: Feb. 18, 2010

(54) Polishing Composition and Polishing Method Using the Same

(75) Inventor: Tianbao DU, Beaverton, OR (US)

Correspondence Address: VIDAS, ARRETT & STEINKRAUS, P.A., SUITE 400, 6640 SHADY OAK ROAD, EDEN PRAIRIE, MN, 55344, US

(73) Assignee: FUJIMI INCORPORATED, Tualatin, OR (US)

(21) Appl. No.: 12/190,897

(22) Filed: Aug. 13, 2008

(51) Int. Cl. C09K 13/00; H01L 21/302

(52) U.S. Cl. 252/79.1; 438/692; 257/E21.242

(57) ABSTRACT

A polishing composition for electrochemical mechanical polishing a surface of an object in which the polishing composition contains a phosphate electrolyte such as a potassium phosphate, a chelating agent such as a potassium citrate, a corrosion inhibitor such as benzotriazole, an oxidizing agent such as hydrogen peroxide, and a solvent such as water. The polishing composition preferably further contains abrasive particles such as colloidal silica particles.

### BACKGROUND OF THE INVENTION

Low dielectric constant films (low-k films) are beginning to be used instead of conventional insulation films. A low dielectric constant film has a mechanical strength lower than that of a conventional insulation film. Therefore, when a semiconductor wafer having a low dielectric constant film is polished by conventional chemical mechanical polishing processes, the low dielectric constant film of the semiconductor wafer may be mechanically damaged. Accordingly, such a semiconductor wafer is often polished by electrochemical mechanical polishing processes.

Electrochemical mechanical polishing is a technique used to remove conductive materials from a semiconductor wafer or substrate surface by electrochemical dissolution while concurrently polishing the substrate at a significantly reduced down force and mechanical abrasion as compared to conventional CMP processes. Electrochemical dissolution is typically performed by applying a voltage to the substrate surface performing as an anode, and applying a voltage to a cathode to remove conductive materials from the substrate surface into a surrounding electrolyte. The voltage may be applied to the substrate surface by a conductive material that is in contact with the substrate or by a conductive material that is not in contact with the substrate but faces close to the substrate. The polishing material may be, for example, a processing pad disposed on a platen. A mechanical component of the polishing process is performed by providing relative motion between the substrate and the polishing material that enhances the removal of the conductive material from the substrate.

The substrate typically begins the planarization process having bulk conductive material deposited thereon in a non-planar orientation, which may be removed by electrochemical mechanical polishing processes. The bulk conductive material removal is designed to produce a high removal rate and produce a substrate surface that is substantially planar before going to the next process. Various chemistries have been developed to promote a higher removal rate of conductive material with lower down force applied to the substrate which makes the process compatible with low-k materials.

### SUMMARY OF THE INVENTION

Accordingly, it is an objective of the present invention to provide a polishing composition suitably usable for electrochemical mechanical polishing a surface of an object, and to provide a method for electrochemical mechanical polishing a surface of an object using the polishing composition.

To achieve the foregoing objective and in accordance with one aspect of the present invention, a polishing composition containing a phosphate electrolyte, a chelating agent, a corrosion inhibitor, an oxidizing agent, and a solvent is provided.

In accordance with another aspect of the present invention, a method for electrochemical mechanical polishing a surface of an object is provided. The object includes a conductive layer provided on an insulation layer having a trench. The conductive layer has a portion positioned outside the trench and a portion positioned inside the trench. The method includes preparing the polishing composition according to the above aspect of the present invention, and exposing an upper surface of the insulation layer by removing the portion of the conductive layer positioned outside the trench through electrochemical mechanical polishing using the polishing composition.

Other aspects and advantages of the invention will become apparent from the following description, illustrating by way of example the principles of the invention.

### BRIEF DESCRIPTION OF THE DRAWINGS

The invention, together with objects and advantages thereof, may best be understood by reference to the following description of the presently preferred embodiments together with the accompanying drawings in which:

FIGS. 1A, 1B, and 1C are cross-sectional views of an object to be polished for explaining a process for forming wiring of a semiconductor device;

### DETAILED DESCRIPTION OF THE PREFERRED EMBODIMENTS

One embodiment of the present invention will be explained below.

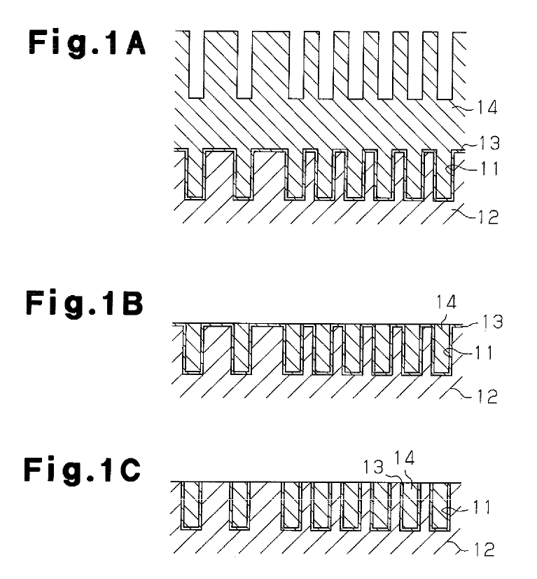

To begin with, a method for forming wiring of a semiconductor device will be explained in accordance with FIGS. 1A to 1C.

As shown in FIG. 1A, first a barrier layer 13 and a conductive layer 14 are successively formed in this order on an insulation layer 12 formed on a semiconductor substrate (not shown) and having wiring trenches 11 with a prescribed design pattern. The barrier layer 13, which is formed on the insulation layer 12 before the conductive layer 14 is formed, covers over the upper surface of the insulation layer 12. The thickness of the barrier layer 13 is less than the depth of the trenches 11. The conductive layer 14, which is formed on the barrier layer 13 after the barrier layer 13 is formed, at least fills up the trenches 11.

Thereafter, at least a portion of the conductive layer 14 (outer portion of the conductive layer 14) positioned outside the trenches 11 and a portion of the barrier layer 13 (outer portion of the barrier layer 13) positioned outside the trenches are removed by electrochemical mechanical polishing. As a result, as shown in FIG. 1C, at least a part of a portion of the barrier layer 13 (inner portion of the barrier layer 13) positioned inside the trenches 11 and at least a part of a portion of the conductive layer 14 (inner portion of the conductive layer 14) positioned inside trenches 11 remain on the insulation layer 12. The portion of the conductive layer 14 remaining on the insulation layer 12 comes to function as wiring of a semiconductor device.

The insulation layer 12 is formed of, for example, silicon dioxide, a carbon-doped silicon oxide (SiOC), or a fluorine-doped silicon oxide (SiOF). The insulation layer 12 may be a low-k SiOC film or a low-k SiOF film. The trenches 11 of the insulation layer 12 are formed by known lithograph and pattern etching techniques.

The barrier layer 13 is formed of, for example, tantalum or a tantalum alloy.

The conductive layer 14 is formed by forming a thin seed layer of conductive material on the barrier layer 13 through, for example, physical vapor deposition (PVD) and then forming a thick layer of conductive material on the seed layer by electroplating. The conductive layer 14 is formed of, for example, copper or a copper alloy.

When at least the outer portion of the conductive layer 14 and the outer portion of the barrier layer 13 are removed by electrochemical mechanical polishing, first, the outer portion of the conductive layer 14 is partially removed so as to expose the upper surface of the outer portion of the barrier layer 13, as shown in FIG. 1B (first polishing step). Thereafter, as shown in FIG. 1C, at least the remaining outer portion of the conductive layer 14 and the outer portion of the barrier layer 13 are removed so as to expose the insulation layer 12 and obtain a planar surface (second polishing step). A polishing composition according to the embodiment is used mainly in the first polishing step and the second polishing step as described above.

A polishing composition according to the embodiment is prepared by dissolving a phosphate electrolyte, a chelating agent, a corrosion inhibitor, and an oxidizing agent in a solvent. Accordingly, the polishing composition contains a phosphate electrolyte, a chelating agent, a corrosion inhibitor, an oxidizing agent, and a solvent.

The phosphate electrolyte is contained in the polishing composition to provide the required conductivity for the polishing composition.

As a phosphate electrolyte to be contained in the polishing composition, a potassium phosphate, an ammonium phosphate, or a mixture of a potassium phosphate and an ammonium phosphate can be used in an advantageous manner.

The content of a phosphate electrolyte in the polishing composition is preferably 1.0% by mass or more, and more preferably 6.0% by mass or more. As the content of a phosphate electrolyte in the polishing composition increases, the conductivity of the polishing composition more increases, resulting in increasing the removal rate of electrochemical mechanical polishing a conductive layer and a barrier layer with the polishing composition. In this regard, when the content of a phosphate electrolyte in the polishing composition is 1.0% by mass or more, and more specifically 6.0% by mass or more, it is easy to increase the removal rate of electrochemical mechanical polishing of a conductive layer and a barrier layer with the polishing composition to an especially suitable level for practical use.

The content of a phosphate electrolyte in the polishing composition is also preferably 15.0% by mass or less, and more preferably 12.0% by mass or less. As the content of a phosphate electrolyte in the polishing composition decreases, the phosphate electrolyte is more inhibited from precipitating in the polishing composition, resulting in improving the solution stability of the polishing composition. In this regard, when the content of a phosphate electrolyte in the polishing composition is 15.0% by mass or less, and more specifically 12.0% by mass or less, it is easy to improve the solution stability of the polishing composition to an especially suitable level for practical use.

The chelating agent is contained in the polishing composition to accelerate the electrochemical mechanical polishing action of the polishing composition upon a conductive layer and a barrier layer through chelating properties.

As a chelating agent to be contained in the polishing composition, a carboxyl acid such as citric acid or a carboxylate such as a potassium citrate can be used in an advantageous manner.

The content of a chelating agent in the polishing composition is preferably 0.1% by mass or more, and more preferably 1.0% by mass or more. As the content of a chelating agent in the polishing composition increases, the electrochemical mechanical polishing action of the polishing composition upon a conductive layer and a barrier layer is more accelerated, resulting in increasing the removal rate of electrochemical mechanical polishing a conductive layer and a barrier layer with the polishing composition. In this regard, when the content of a chelating agent in the polishing composition is 0.1% by mass or more, and more specifically 1.0% by mass or more, it is easy to increase the removal rate of electrochemical mechanical polishing a conductive layer and a barrier layer with the polishing composition to an especially suitable level for practical use.

The content of a chelating agent in the polishing composition is also preferably 5.0% by mass or less, and more preferably 3.0% by mass or less. As the content of a chelating agent in the polishing composition decreases, the corrosion action of the polishing composition upon a conductive layer and a barrier layer is more prevented from excessively increasing, resulting in ease of obtaining a planar surface by electrochemical mechanical polishing with the polishing composition. In this regard, when the content of a chelating agent in the polishing composition is 5.0% by mass or less, and more specifically 3.0% by mass or less, it is easy to improve the planarity of the surface after electrochemical mechanical polishing with the polishing composition to an especially suitable level for practical use.

The corrosion inhibitor is contained in the polishing composition to passivate the exposed surfaces of a conductive layer and a barrier layer, thereby inhibiting the excessive corrosion on the layers by the polishing composition.

As a corrosion inhibitor to be contained in the polishing composition, a compound having a triazole ring such as triazole, 3-aminotriazole, benzotriazole, and 5-carboxybenzotriazole can be used in an advantageous manner. Benzotriazole is most preferable because it has a strong passivation behavior and is easy to handle.

The content of a corrosion inhibitor in the polishing composition is preferably 0.1% by mass or more, and more preferably 0.2% by mass or more. As the content of a corrosion inhibitor in the polishing composition increases, the excessive corrosion on a conductive layer and a barrier layer by the polishing composition is more inhibited, resulting in ease of obtaining a planar surface by electrochemical mechanical polishing with the polishing composition. In this regard, when the content of a corrosion inhibitor in the polishing composition is 0.1% by mass or more, and more specifically 0.2% by mass or more, it is easy to improve the planarity of the surface after electrochemical mechanical polishing with the polishing composition to an especially suitable level for practical use.

The content of a corrosion inhibitor in the polishing composition is also preferably 1.0% by mass or less, and more preferably 0.4% by mass or less. As the content of a corrosion inhibitor in the polishing composition decreases, the corrosion inhibitor is more inhibited from precipitating in the polishing composition, resulting in improving the solution stability of the polishing composition. Further, as the content of a corrosion inhibitor in the polishing composition decreases, the removal rate of electrochemical mechanical polishing a conductive layer and a barrier layer with the polishing composition is more prevented from decreasing due to the passivation of the exposed surfaces of the conductive layer and the barrier layer by the corrosion inhibitor, resulting in increasing the removal rate of electrochemical mechanical polishing a conductive layer and a barrier layer with the polishing composition. In this regard, when the content of a corrosion inhibitor in the polishing composition is 1.0% by mass or less, and more specifically 0.4% by mass or less, it is easy to improve the solution stability of the polishing composition to an especially suitable level for practical use, and to increase the removal rate of electrochemical mechanical polishing a conductive layer and a barrier layer with the polishing composition to an especially suitable level for practical use.

The oxidizing agent is contained in the polishing composition to accelerate the electrochemical mechanical polishing action of the polishing composition upon a conductive layer and a barrier layer through oxidizing properties.

As an oxidizing agent to be contained in the polishing composition, hydrogen peroxide, ammonium persulfate, or potassium persulfate can be used in an advantageous manner. Hydrogen peroxide is most preferable because it is easily available and contains only a small amount of metallic impurities.

The content of an oxidizing agent in the polishing composition is preferably 0.5% by mass or more, and more preferably 1.0% by mass or more. As the content of an oxidizing agent in the polishing composition increases, the electrochemical mechanical polishing action of the polishing composition upon a conductive layer and a barrier layer is more accelerated, resulting in increasing the removal rate of electrochemical mechanical polishing a conductive layer and a barrier layer with the polishing composition. In this regard, when the content of an oxidizing agent in the polishing composition is 0.5% by mass or more, and more specifically 1.0% by mass or more, it is easy to increase the removal rate of electrochemical mechanical polishing a conductive layer and a barrier layer with the polishing composition to an especially suitable level for practical use.

The content of an oxidizing agent in the polishing composition is also preferably 25.0% by mass or less, and more preferably 10.0% by mass or less. As the content of an oxidizing agent in the polishing composition decreases, the corrosion action of the polishing composition upon a conductive layer and a barrier layer is more prevented from excessively increasing, resulting in ease of obtaining a planar surface by electrochemical mechanical polishing with the polishing composition. In this regard, when the content of an oxidizing agent in the polishing composition is 25.0% by mass or less, and more specifically 10.0% by mass or less, it is easy to improve the planarity of the surface after electrochemical mechanical polishing with the polishing composition to an especially suitable level for practical use.

The solvent is contained in the polishing composition to dissolve a phosphate electrolyte, a chelating agent, a corrosion inhibitor, and an oxidizing agent.

As a solvent to be contained in the polishing composition, water can be used in an advantageous manner.

The pH of the polishing composition is preferably in a range of 4 to 9, more preferably in a range of 4 to 7, and even more preferably 4 to 6. When the pH of the polishing composition is in a range of 4 to 9, more specifically in a range of 4 to 7, and even more specifically in a range of 4 to 6, it is easy to increase the removal rate of electrochemical mechanical polishing a conductive layer and a barrier layer with the polishing composition to an especially suitable level for practical use.

The above-mentioned embodiment may be modified as follows.

The polishing composition according to the above-mentioned embodiment may further contain abrasive particles to enhance the mechanical polishing properties of the polishing composition.

As abrasive particles to be contained in the polishing composition, particles of metal oxide such as silicon oxide, aluminum oxide, cerium oxide, zirconium oxide, and titanium oxide or particles of metal carbide such as silicon carbide can be used in an advantageous manner. In order to obtain a surface with low roughness by electrochemical mechanical polishing with the polishing composition, silicon oxide particles (SiO₂ particles) or aluminum oxide particles (Al₂O₃ particles) are preferable, and silicon oxide particles such as colloidal silica particles and fumed silica particles are more preferable, and colloidal silica particles are most preferable. The abrasive particles may be modified by an organic functional group.

From the viewpoint of enhancing the mechanical polishing properties of the polishing composition, the content of abrasive particles in the polishing composition is preferably 0.1% by mass or more, and more preferably 0.2% by mass or more.

Further, in order to achieve a high dispersion stability of the abrasive particles in the polishing composition, the content of abrasive particles in the polishing composition is preferably 5.0% by mass or less, and more preferably 3.0% by mass or less.

Colloidal silica particles to be contained in the polishing composition have an average particle size measured by a laser diffraction method preferably in a range of from 10 to 150 nm, and more preferably in a range of from 20 to 70 nm.

Fumed silica particles to be contained in the polishing composition have an average particle size measured by a laser diffraction method preferably in a range of from 30 to 200 nm, and more preferably in a range of from 50 to 100 nm.

Aluminum oxide particles to be contained in the polishing composition preferably have an average particle size measured by an electric resistance method (a Coulter method) in a range of from 30 to 100 nm.

The polishing composition according to the above-mentioned embodiment may further contain one or more additive ingredients such as a pH adjuster, a surfactant, a polymer, and an antifoaming agent

The polishing composition according to the above-mentioned embodiment may be prepared by diluting with water an undiluted polishing composition. The undiluted polishing composition is easy to store and transport.

The polishing composition according to the above-mentioned embodiment may be provided as a one-part product which is stored in one container containing all components or as a multi-part product as represented by a two-part product which is dividedly stored in two containers.

The object to be polished shown in FIGS. 1A to 1C does not necessarily include the barrier layer 13. In the case where the object to be polished does not include the barrier layer 13, the conductive layer 14 is formed directly on the insulation layer 12.

Examples of the present invention will be described hereunder.

Polishing compositions according to Examples 1 to 5 were each prepared by mixing a phosphate electrolyte, a chelating agent, a corrosion inhibitor, an oxidizing agent, and abrasive particles with water (a solvent). The details of a phosphate electrolyte, a chelating agent, a corrosion inhibitor, an oxidizing agent, and abrasive particles contained in each polishing composition, and the results of measuring the pH of the polishing compositions are shown in Table 1. Any of colloidal silica particles used as abrasive particles in each polishing composition has an average particle size calculated based on the specific surface of the colloidal silica particles, which is measured by a BET method, of 35 nm and an average particle size measured by a laser diffraction method of 72 nm.

The column entitled “Removal rate” in Table 1 shows results of evaluating the removal rate of electrochemical mechanical polishing a copper blanket wafer using each polishing composition under the conditions shown in Table 2. The removal rate of each polishing composition was evaluated by dividing the difference in thickness of each wafer between before and after polishing by polishing time. The thickness of each wafer was measured by a resistance meter “VR-120” manufactured by Kokusai Electric System Service Co., Ltd.

The column entitled “Planarization efficiency” in Table 1 shows results of evaluating the planarization efficiency when a copper patterned wafer was electrochemical mechanical polishing using each polishing composition under the conditions shown in Table 2. The planarization efficiency of each polishing composition was evaluated by dividing the difference in step height of each wafer surface between before and after polishing by material removal thickness. The step height of each wafer was measured by a contact type profiler “HRP 340” manufactured by KLA-Tencor Corporation.

TABLE 1

| | Phosphate | Chelating | Corrosion | Oxidizing | Abrasive | | Removal rate | Planarization |
|---|---|---|---|---|---|---|---|---|
| | electrolyte | agent | inhibitor | agent | particles | pH | [μm/minute] | efficiency |
| Example 1 | KH₂PO₄ | K₃C₆H₅O₇•H₂O | Benzotriazole | H₂O₂ | Colloidal silica | 5.10 | 0.8 | 100% |
| | 10.6% | 1.8% | 0.3% | 1.0% | 1.0% | | | |
| Example 2 | KH₂PO₄ | K₃C₆H₅O₇•H₂O | Benzotriazole | H₂O₂ | Colloidal silica | 5.10 | 3 | 80% |
| | 10.6% | 1.8% | 0.3% | 10.0% | 1.0% | | | |
| Example 3 | KH₂PO₄ | K₃C₆H₅O₇•H₂O | Benzotriazole | H₂O₂ | Colloidal silica | 5.10 | 2 | 60% |
| | 10.6% | 1.8% | 0.1% | 1.0% | 1.0% | | | |
| Example 4 | KH₂PO₄ | K₃C₆H₅O₇•H₂O | Benzotriazole | H₂O₂ | Colloidal silica | 5.10 | 0.4 | 100% |
| | 10.6% | 0.9% | 0.3% | 1.0% | 1.0% | | | |
| Example 5 | KH₂PO₄ | K₃C₆H₅O₇•H₂O | Benzotriazole | H₂O₂ | Colloidal silica | 5.70 | 0.6 | 95% |
| | 5.3% | 1.8% | 0.3% | 1.0% | 1.0% | | | |

TABLE 2

| | | |
|---|---|---|
| Applied voltage: | 3.0 | V |
| Downward pressure of head: | 0.41 | psi |
| Rotation speed of platen: | 84 | rpm |
| Rotation speed of head: | 62 | rpm |
| Feeding speed of the polishing composition: | 58 | mL/minute |
| Polishing time: | 1 | minute |

1. A polishing composition for electrochemical mechanical polishing a surface of an object, the polishing composition comprising:
a phosphate electrolyte;
a chelating agent;
a corrosion inhibitor;
an oxidizing agent; and
a solvent.

2. The polishing composition according to claim 1, wherein the phosphate electrolyte is a potassium phosphate, an ammonium phosphate, or a mixture of a potassium phosphate and an ammonium phosphate.

3. The polishing composition according to claim 1, wherein the content of a phosphate electrolyte in the polishing composition is in a range of from 1.0 to 15.0% by mass.

4. The polishing composition according to claim 1, wherein the chelating agent is a carboxyl acid or a carboxylate.

5. The polishing composition according to claim 1, wherein the content of a chelating agent in the polishing composition is in a range of from 0.1 to 5.0% by mass.

6. The polishing composition according to claim 1, wherein the corrosion inhibitor is a compound having a triazole ring.

7. The polishing composition according to claim 1, wherein the content of a corrosion inhibitor in the polishing composition is in a range of from 0.1 to 1.0% by mass.

8. The polishing composition according to claim 1, wherein the oxidizing agent is hydrogen peroxide, ammonium persulfate, or potassium persulfate.

9. The polishing composition according to claim 1, wherein the content of an oxidizing agent in the polishing composition is in a range of from 0.5 to 25.0% by mass.

10. The polishing composition according to claim 1, wherein the pH of the polishing composition is in a range of from 4 to 9.

11. The polishing composition according to claim 1, further comprising abrasive particles.

12. The polishing composition according to claim 11, wherein the abrasive particles are silicon oxide particles.

13. The polishing composition according to claim 11, wherein the content of abrasive particles in the polishing composition is in a range of from 0.1 to 5.0% by mass.

14. A polishing composition for electrochemical mechanical polishing of a surface of an object, the polishing composition comprising:
a potassium phosphate of a content in a range of from 6.0 to 12.0% by mass in the polishing composition;
a potassium citrate of a content in a range of from 1.0 to 3.0% by mass in the polishing composition;
benzotriazole of a content in a range of from 0.2 to 0.4% by mass in the polishing composition;
hydrogen peroxide of a content in the range of from 1.0 to 10.0% by mass in the polishing composition; and
water, wherein the pH of the polishing composition is in a range of from 4 to 9.

15. The polishing composition according to claim 14, further comprising abrasive particles.

16. The polishing composition according to claim 15, wherein the abrasive particles are colloidal silica particles, and the content of colloidal silica particles in the polishing composition is in a range of from 0.1 to 5.0% by mass.

17. The polishing composition according to claim 16, wherein the colloidal silica particles have an average particle size measured by a laser diffraction method in a range of from 20 to 70 nm.

18. A method for electrochemical mechanical polishing a surface of an object, wherein the object includes a conductive layer provided on an insulation layer having a trench, and the conductive layer has a portion positioned outside the trench and a portion positioned inside the trench, the method comprising:
preparing a polishing composition containing:
a phosphate electrolyte;
a chelating agent;
a corrosion inhibitor;
an oxidizing agent; and
a solvent; and
exposing an upper surface of the insulation layer by removing the portion of the conductive layer positioned outside the trench through electrochemical mechanical polishing using the polishing composition.

19. The method according to claim 18, wherein the object to be polished further includes a barrier layer provided between the insulation layer and the conductive layer for preventing a constituting element of the conductive layer from diffusing to the insulation layer, the barrier layer having a portion positioned outside the trench and a portion positioned inside the trench, and
wherein said exposing an upper surface of the insulation layer includes, in addition to removing the portion of the conductive layer positioned outside the trench, removing the portion of the barrier layer positioned outside the trench through electrochemical mechanical polishing using the polishing composition.

20. The method according to claim 19, wherein the conductive layer is formed of copper or a copper alloy, and the barrier layer is formed of tantalum or a tantalum alloy.
